(19) United States
(12) Patent Application Publication
(10) Pub. No.: US 2007/0261957 A1
(43) Pub. Date: Nov. 15, 2007

(54) Magnetron cathode and sputtering device installing it

(76) Inventor: Nobuyuki Takahashi, Sagamihara (JP)

Correspondence Address: WENDEROTH, LIND & PONACK, L.L.P., 2033 K STREET N. W., SUITE 800, WASHINGTON, DC, 20006-1021, US

(21) Appl. No.: 11/797,289

(22) Filed: May 2, 2007

(30) Foreign Application Priority Data
May 9, 2006 (JP) 2006-130290

(51) Int. Cl. C23C 14/00

(52) U.S. Cl. 204/298.16

(57) ABSTRACT

The present invention provides a magnetron cathode comprising a circular inner target and an outer target provided outside said inner target and concentrically to said inner target, wherein an outer magnet unit positioned behind said outer target, immovable against a back panel portion for outer target holding said outer target, and comprising an magnet group for outer target and an outer yoke on which said magnet group for outer target is fixed, an inner magnet unit positioned behind said inner target, provided movably and rotatably on a back panel portion for inner target, and comprising an magnet group for inner target and an inner yoke on which said magnet group for inner target is fixed, a movement control means for moving said inner magnet unit to said inner target; and a rotation control means for rotating said inner magnet unit to said inner target are provided, so that improvement of distribution and uniformity of erosion of the targets are achieved and further increase of availability and life of the targets are achieved.

### BACKGROUND OF THE INVENTION

This invention relates to a magnetron cathode comprising a circular inner target and an outer target which is provided around the inner target concentrically and relates to a sputtering device installing it.

JP 3-6221 B discloses a vacuum sputtering device that comprises a target means which has a first target having a flat substance radiating surface firstly and a second target having a concave substance radiating surface in order to sputter the substance from the target means to a processed matter. Besides, the device comprises a magnet field forming means for generating magnet field crossing to ionic electric field near both radiating surface of the first and second surfaces and a means for installing the both targets so that radiated substance is sputtered from the concave radiating surface outside the first target against the flat radiating surface with a specific angle.

The above reference discloses a magnetron sputtering device having a flat target and a concave target, which has a problem such that it is difficult to produce the targets because the inner target and the ring-shaped target are not flat and one of them is concave. Besides, on the contrary, there is a disadvantage that distribution thereof is not made better in the case that one of the targets is formed concavely. Furthermore, there is a further disadvantage that the target can not be sputtered all over the surface thereof, it is difficult to increase the film quality and utility efficiency of the targets is not good. Moreover, there is a problem that distribution, whole surface erosion and utility efficiency of targets are bad because a yoke forming a magnetic circuit is united and magnets are secured.

### SUMMARY OF THE INVENTION

Accordingly, the present invention provides a magnetron cathode which designs to uniformize erosion of the targets and designs to increase utility efficiency and life of the targets and provides a sputtering device installing it.

Therefore, the present invention provides a magnetron cathode comprising a circular inner target and an outer target providing outside the inner target concentrically, further comprising: an outer magnet unit which is immovable against a back panel portion for outer target positioning behind the outer target and holding the outer target and which includes a magnet group for outer target and an outer yoke on which the magnet group for outer target is fixed; an inner magnet unit which is provided rotatably and movable against a back panel for inner target positioned behind the inner target and which includes a magnet group for inner target and an inner yoke on which the magnet group for inner target is fixed; a movement control means for moving the inner magnet unit against the inner target; and a rotation control means for rotating the inner magnet unit against the inner target.

Furthermore, it is preferred that the magnetron cathode of the present invention further comprises a magnetic flux density detection means for detecting magnetic flux density adjacent to the inner magnet unit which is located near the inner magnet unit, and controls the movement control means based on the magnetic flux density detected by the magnetic flux density detection means.

Moreover, it is preferred that the magnet group for outer target comprises an outer magnet group and an inner magnet group which are provided side by side in a radial direction, wherein magnetic pole surfaces of the outer magnet group and the inner magnet group are formed so as to be a difference in level, namely so that an outer target side magnetic pole surface of the outer magnet group is nearer to the outer target than an outer target side magnetic pole surface of the inner magnet group.

Besides, it is preferred that a magnetic ring formed circularly along the back plate portion for outer target is provided between the back plate portion for outer target and the magnet group for outer target. Furthermore, it is preferred that a non-magnetic ring (a first non-magnetic ring) circularly along the magnetic ring is provided between the magnetic ring and the magnet group for outer target. Moreover, it is preferred that an inner magnetic ring formed circularly along the first non-magnetic ring and a non-magnetic ring (a second non-magnetic ring) formed circularly along the inner magnetic ring and located between the inner magnetic ring and the inner magnet group are provided between the inner magnet group and the first non-magnetic ring of the magnet group for outer target.

Besides, it is preferred that a magnetic material is located between the outer target and the back plate for outer target.

Moreover, the inner magnet group in the inner magnet unit is preferably constituted of an outer peripheral magnet group and a center magnet group which are movable independently. Furthermore, a disc-like magnetic plate may be located on an inner target side end portion of the center magnet group and a circular magnetic plate may be located on an inner target side end portion of the outer peripheral magnet group. Besides, the center magnet group may be rotated in the opposite direction of the outer magnet group, but may be rotated at a different rotation rate in a same direction to the outer magnet group.

Furthermore, the inner target and the outer target may consist of a same material, but also the inner target and the outer target may consist of different materials respectively. Besides, it is preferred that the inner target and the outer target are sputtered simultaneously, but also the inner target and the outer target are sputtered independently.

Moreover, a magnetic plate ununiformly extending from a center portion thereof may be provided on the inner magnet unit side surface of the back plate for inner target.

According to the present invention, by providing the circular inner target and the outer target providing outside the inner target concentrically with the inner target and further by providing the outer magnet unit fixed behind of the outer target and the inner magnet unit provided rotatably and movably behind the inner target, because whole surfaces of the inner target and the outer target can be sputtered, the whole surfaces can be cleaned simultaneously with sputtering and adhesion of alien substances to the targets is prevented, so that an effect that sputtering the cleaned target prevents mixing the alien substances into a thin film is achieved. Furthermore, thus, increase of film quality (magnetic quality of the magnetic film and the like) is achieved. Moreover, as improvement of the distribution and erosion evenness of the inner target and the outer target can be achieved, an effect such that utilization efficiency of the target and a life of target are increased can be achieved.

Besides, because the inner magnet unit can be moved so that magnetic flux density after sputtering is compared with the magnetic flux density at initial sputtering by means of using a magnetic sensor such as a hall device in order to meet to it, distribution of the target during sputtering can be increased and increase of whole surface erosion can be obtained, so that film quantity and a life of the target can be improved.

Furthermore, since the outer magnet group and the inner magnet group constituting the magnet group for outer target are formed in a stepped shape, magnet field can be distributed all over the outer target, so that an effect such that a sputtering area of the outer target can be eroded all over the surface thereof is achieved.

By providing a magnetic ring having a non-magnetic ring as a spacer, since it is possible to adjust a magnetic flux on the outer target availably, the maximum magnetic flux part on the outer target can be moved to a peripheral portion on the outer target, so that an effect such that availability of the target can be increased is achieved.

Besides, by providing a magnetic material between the outer target and the back panel portion for outer target, since stabilization of the magnetic flux on the target can be achieved, stabilization of electric discharge is achieved, so that control of film thickness can be facilitated. Especially, in the case that the inner target is a magnet material and the outer target is a non-magnetic material, by providing the magnetic plate into the outer target to hold the magnetic flux, since the magnetic flux is difficult to be influenced by the magnetic material of the inner target, an effect such that the electric discharge is stable can be obtained.

Furthermore, by rotating the outer peripheral magnet group and the center magnet group constituting the inner magnet unit relatively, high speed rotation becomes possible and formation of the thinnest film becomes possible.

Moreover, since the magnetic plate expanding from a center thereof heterogeneously is provided behind the back panel portion for inner target and the magnetic plate are provided at end portions of the outer peripheral magnet group and the center magnet group of the inner magnet unit, strength of the magnetic flux density and a shape of the magnet flux beam of an upper surface of the inner target can be controlled strictly, so that erosion area expanding to a whole surface of the target, availability of the target and distribution of film thickness can be achieved.

### BRIEF DESCRIPTION OF THE DRAWINGS

FIG. 1 is a schematic diagram of a magnetron cathode according to the present invention;

FIG. 2 is an enlarged sectional diagram showing an area adjacent to an outer magnet unit;

FIG. 3 is a schematic diagram of a control device; and

FIG. 4 is an explanation diagram of a magnetic plate.

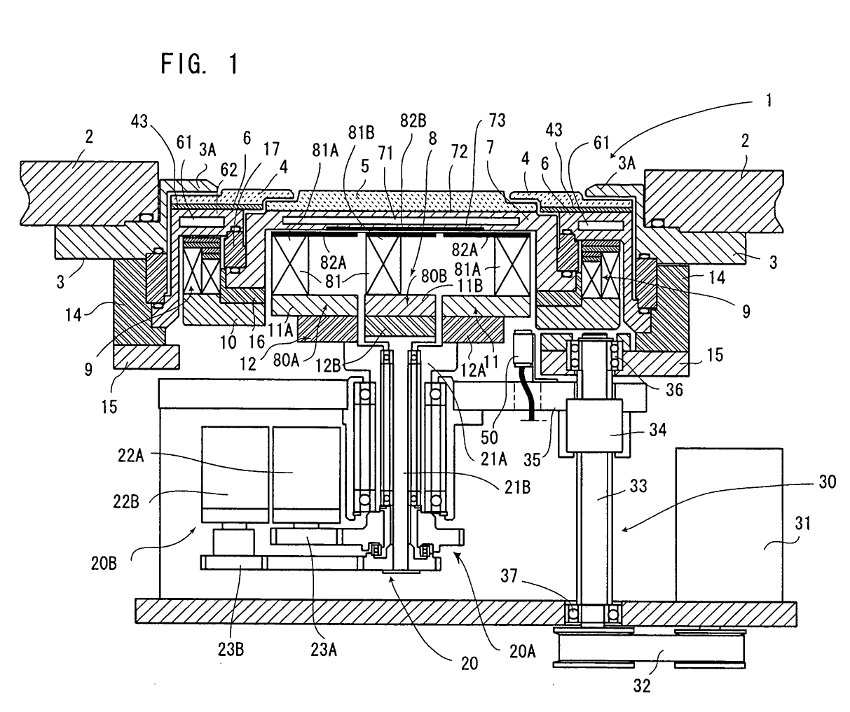

### DETAILED DESCRIPTION OF THE PREFERRED EMBODIMENT

Hereinafter, the preferred embodiment of this invention is explained by referring drawings.

A magnetron cathode 1 according to the embodiment of the present invention used in a sputtering device is installed via an installation portion 3 on a housing 2 defining a sputtering space in which a substrate for thin film formation not shown in figures. Note that the installation portion 3 has a shield portion 3A extending around an outer target 4.

The outer target 4 is formed circularly and an inner target 5 is located inside of the outer target 4. Besides, the outer target 4 is installed on a back panel portion for outer target 62 constituting a part of an outer target back panel block 6 fixed on the installation portion 3 via an insulated supporting block 14, and is cooled by cooling water passing through a cooling water flowing path 61 formed inside the back panel portion for outer target 62.

The inner target 5 is installed on a back panel portion for inner target 72 in an inner target back panel block 7 fixed to the outer target back panel block 6 via an insulated member 17 and is cooled by cooling water passing through a cooling water flowing path 71 formed inside the back panel portion for inner target 72. Besides, the inner target back panel block 7 is formed cylindrically such that the back panel portion for inner target 72 is a bottom surface thereof, inside which an inner magnet unit 8 is located.

The inner magnet unit 8 is constituted of at least a magnet group for inner target 81, an inner yoke 11 on which the magnet group for inner target 81, an inner magnet unit rotation mechanism 20 for rotating the inner magnet unit 8 and a inner magnet unit vertical movement mechanism 30 for moving the inner magnet unit 8 toward or away from the inner target 5.

Besides, in this embodiment, the inner target unit 8 is constituted of an outer peripheral magnet unit 80A and a center magnet unit 80B. The outer peripheral magnet unit 80A is constituted of at least an outer peripheral magnet group 81A, an outer peripheral yoke 11A constituting a part of the inner yoke 11, an outer peripheral insulator 12A constituting a part of an insulator 12 and an outer peripheral rotation shaft 21A for rotating the outer peripheral magnet group 81A. The center magnet unit 80B is constituted of at least a center magnet group 81B, a center yoke 11B constituting another part of the inner yoke 11, a center insulator 12B constituting another part of the insulator 12 and a center rotation shaft 21B for rotating the center magnet group 81B. Besides, a circular magnetic plate 82A is fixed on an end portion of the outer peripheral magnet group 81A which faces the inner target, and a circular magnetic plate 82B is fixed on an end portion of the center magnet group 81B which faces the inner target.

Furthermore, as shown in FIG. 4, a magnetic plate 73 with a shape such as to extend heterogeneously from a center portion of the inner target 5, for instance, a square shape which has four corners with different angles and four different lines is provided on a surface of the back panel portion for inner target 72 facing the center magnet group 81B.

Besides, the inner magnet unit rotation mechanism 20 is constituted of an outer magnet group rotation mechanism part 20A and a center magnet group rotation mechanism part 20B. The outer magnet group rotation mechanism part 20A is constituted of a gear 23A connected with the outer peripheral rotation shaft 21A and an electric motor 22A for rotating it. The inner magnet group rotation mechanism part 20B is constituted of a gear unit 23B connected with the center rotation shaft 21B and an electric motor 22B for rotating it.

The inner magnet unit vertical movement mechanism 30 is constituted of at least a supporting arm 35 supporting a unit comprising the inner magnet unit rotation mechanism 20 and the inner magnet unit 8, a screwed rotation shaft 33 supported rotatably to a fixing portion 15 fixed in an insulated supporting block 14 via bearings 36 and 37, a movement portion 34 on which the supporting arm 35 is fixed and which moves up and down along the screwed rotation shaft 33 with rotation of the screwed rotation shaft 33, an electric motor 31 for rotating the screw rotation shaft 33 and a belt mechanism 32 for connecting the screwed rotation shaft 33 with the electric motor 31.

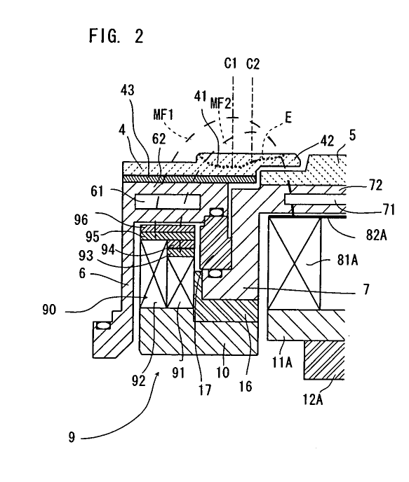

An outer magnet unit 9 fixed on the back panel portion for outer target 62 is, as shown in detail in FIG. 2, constituted of at least an outer yoke 10 fixed on an end portion of the inner target back panel block 7 via an insulator 16 and an outer target magnet group 90 fixed between the outer yoke 10 and the back panel portion for outer target 62 of the outer target back panel block 6. Besides, a magnetic plate 43 is provided between the outer target 4 and the back panel portion for outer target 62.

The outer target magnet group 90 comprises an outer magnet group 92 and an inner magnet group 91, and outer target side magnetic pole surfaces of the outer magnet group 92 and the inner magnet group 91 are formed stepwise so that the outer target side magnetic pole surface of the outer magnet group 92 is nearer to the outer target 4 than the outer target side magnetic pole surface of the inner magnet group 91.

an inner magnetic ring 94 is provided on the outer target side magnetic pole surface of the inner magnet group 91 in the outer target magnet group 90 via an inner non-magnetic ring 93 as a spacer. Furthermore, a magnetic ring 96 is provided on the outer target side magnetic pole surfaces of the inner magnetic ring 94 and the outer magnet group 92 via a non-magnetic ring 95 as a spacer.

Thus, as shown in FIG. 2, because a peak C1 of the magnetic flux MF1 between the outer magnet group 92 and the magnet group for inner target 81 can be moved on an outer peripheral portion 41 with the thickest portion of the outer target 4, amount of sputtering in the outer peripheral portion 41 can be increased. Besides, because sputtering in a thin inner peripheral portion 42 in the inner target side can be ensured by the magnetic flux MF2 between the inner magnet group 91 and the inner target magnet group 81 whose magnetic pole surfaces are away from each other, sputtering all over the outer target can be possible, so that cleaning by the sputtering is performed in the thin inner peripheral portion 42, and in result, mixture of an alien substance into a thin film formed on the substrate by sputtering can be prevented. Furthermore, thus entire erosion E can be formed.

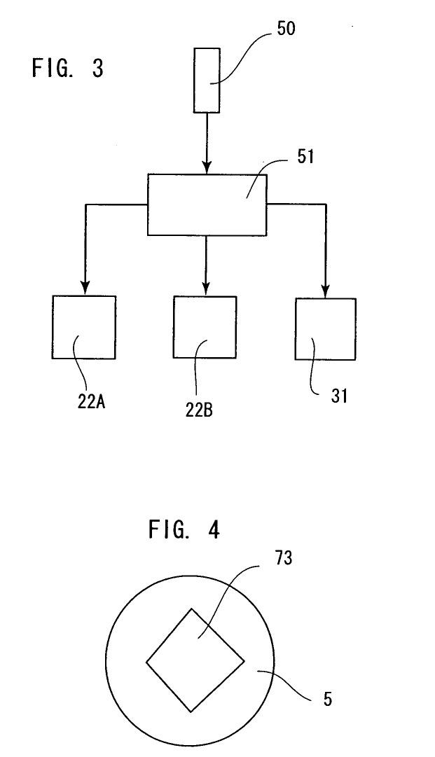

Besides, a magnetic sensor 50 comprising a hall element and the like is arranged adjacent to the inner magnet unit 8. The magnetic sensor 50 is, as shown in FIG. 3, connected with a control unit 51 for controlling the entire sputtering device in which the magnetron cathode 1 according to the present invention is installed. In the control unit 51, magnetic flux density after sputtering is compare with magnetic flux density at initial sputtering, and then the inner magnet unit 8 is moved by controlling the electric motor 31 so as to maintain the magnetic flux density at the initial sputtering. Furthermore, the control unit 51 controls the electric motors 22A and 22B for rotating the inner magnet unit 8 at the same time.

Concretely, in the sputtering device comprising the magnetron cathode 1 having the abovementioned constitution, in the case of sputtering only the inner target 5 especially consisting of a magnetic material, for example when the magnetic flux density is larger than the magnetic flux density at the initial sputtering, the inner magnet unit 8 is moved away from the inner target 5, and when the magnetic flux density is smaller than the magnetic flux density at the initial sputtering, the inner magnet unit 8 is moved toward the inner target 5.

Similarly, in the case of sputtering only the outer target 4 especially consisting of a magnetic material, for example when the magnetic flux density is larger than the magnetic flux density at the initial sputtering, the inner magnet unit 8 is moved away from the inner target 5, and when the magnetic flux density is smaller than the magnetic flux density at the initial sputtering, the inner magnet unit 8 is moved toward the inner target 5. Thus, also in case of the outer target, the same or similar effects can be obtained.

Furthermore, in the case of sputtering the outer target 4 consisting of the magnetic material and the inner target 5 consisting of the magnetic material at the same time, for example when the magnetic flux density is larger than the magnetic flux density at the initial sputtering, the inner magnet unit 8 is moved away from the inner target 5, and when the magnetic flux density is smaller than the magnetic flux density at the initial sputtering, the inner magnet unit 8 is moved toward the inner target 5. Thus, also in the case of sputtering simultaneously, the same or similar effects can be achieved.

What is claimed is:

1. A magnetron cathode comprising:
a circular inner target;
an outer target provided outside said inner target and concentrically to said inner target;
an outer magnet unit positioned behind said outer target, immovable against a back panel portion for outer target holding said outer target, and comprising an magnet group for outer target and an outer yoke on which said magnet group for outer target is fixed;
an inner magnet unit positioned behind said inner target, provided movably and rotatably on a back panel portion for inner target, and comprising an magnet group for inner target and an inner yoke on which said magnet group for inner target is fixed;
a movement control means for moving said inner magnet unit to said inner target; and
a rotation control means for rotating said inner magnet unit to said inner target.

2. A magnetron cathode according to claim 1 further comprising a magnetic flux density detecting means located near said inner magnet unit and detecting magnetic flux density near said inner magnet unit, wherein said movement control means is controlled on said magnetic flux density detected by said magnetic flux density detecting means.

3. A magnetron cathode according to claim 2, wherein:
said magnet group for outer target comprises an outer magnet group and an inner magnet group which are placed side by side in a radial direction thereof, and
outer target side magnetic pole surfaces of said outer magnet group and said inner target group are formed stepwise so that said outer target side magnetic pole surface of said outer magnet group is nearer to said outer target than said outer target side magnetic pole surface of said inner magnet group.

4. A magnetron cathode according to claim 3, wherein:
a magnetic ring formed circularly along said back panel portion for outer target is provided between said back panel portion for outer target and said magnet group for outer target.

5. A magnetron cathode according to claim 4, wherein:
a first non-magnetic ring formed circularly along said magnetic ring is provided between said magnetic ring and said magnet group for outer target,
an inner magnetic ring formed circularly along said first non-magnetic ring and a second non-magnetic ring formed circularly along said inner magnetic ring and located between said inner magnetic ring and said inner magnet group are provided between said inner magnet group of said magnet group for outer target and said first non-magnetic ring.

6. A magnetron cathode according to claim 5, wherein:
a magnetic member is located between said outer target and said back panel portion for outer target.

7. A magnetron cathode according to claim 6, wherein:
an inner magnet group of said inner magnet unit is constituted of an outer peripheral magnet group and a center magnet group which are rotatable independently,
a disc-like magnetic plate is located on an inner target side end potion of said center magnet group, and
a circular magnetic plate is located on an inner target side end portion of said outer peripheral magnet group.

8. A magnetron cathode according to claim 7, wherein:
a magnetic plate with a shape expanding heterogeneously from a center thereof is provided on a surface of said back panel portion for inner target facing said inner magnet unit.

9. A magnetron cathode according to claim 8, wherein:
said inner target and said outer target consist of the same material.

10. A magnetron cathode according to claim 8, wherein:
said inner target and said outer target consist of different materials.

11. A magnetron cathode according to claim 9, wherein:
said inner target and said outer target are sputtered simultaneously.

12. A magnetron cathode according to claim 10, wherein:
said inner target and said outer target are sputtered simultaneously.

13. A magnetron cathode according to claim 9, wherein:
said inner target and said outer target are sputtered independently.

14. A magnetron cathode according to claim 10, wherein:
said inner target and said outer target are sputtered independently.

15. A sputtering device installing said magnetron cathode according to claim 1.

16. A sputtering device installing said magnetron cathode according to claim 8.

17. A sputtering device installing said magnetron cathode according to claim 9.

18. A sputtering device installing said magnetron cathode according to claim 10.

19. A sputtering device installing said magnetron cathode according to claim 11.

20. A sputtering device installing said magnetron cathode according to claim 12.

21. A sputtering device installing said magnetron cathode according to claim 13.

22. A sputtering device installing said magnetron cathode according to claim 14.
